(19) United States
(12) Patent Application Publication
(10) Pub. No.: US 2020/0318729 A1
(43) Pub. Date: Oct. 8, 2020

(54) DETECTING DEVICE

(71) Applicant: Valeo Japan Co., Ltd., Saitama (JP)

(72) Inventor: Masanori Endo, Tokyo (JP)

(21) Appl. No.: 16/839,071

(22) Filed: Apr. 2, 2020

(30) Foreign Application Priority Data
Apr. 3, 2019 (JP) 2019-071194

(51) Int. Cl. F16H 59/10; G01R 33/07

(52) U.S. Cl. CPC F16H 59/105; G01R 33/07

(57) ABSTRACT

A detecting device detecting an operation of a detection object may include a movable member that may move in association with the operation of the detection object, a fixing member that may movably support the movable member, a single magnet that may be disposed in the movable member and in which an N pole and an S pole may line in a movement direction of the movable member, and a single magnetic sensor disposed in the fixing member. The magnetic sensor may be arranged to be opposed to the magnet on a movement track of the magnet as viewed in a direction perpendicular to the movement direction of the movable member.

### CROSS-REFERENCE TO RELATED APPLICATION

This application claims priority under 35 USC 119 from Japanese Patent Application No. 071194/2019 filed on Apr. 3, 2019, the disclosure of which is incorporated by reference herein.

### TECHNICAL FIELD

The present invention relates to a detecting device.

### BACKGROUND

Japanese Patent No. 4650796 discloses a detecting device (a range detection device) that is used for detection of a selection range in an automatic transmission.

The detecting device disclosed in Japanese Patent No. 4650796 includes a movable member that moves in association with a switch of the selection range and a fixing member that movably supports the movable member.

A plurality of magnets are disposed in the inside of the movable member. In the movable member, the plurality of magnets line to be spaced from each other in a direction perpendicular to a movement direction of the movable member. N poles and S poles alternately line in the movement direction of the movable member in each of the magnets.

The fixing member is provided with a plurality of HALL ICs (magnetic sensors). The HALL ICs are disposed as many as the magnets in a one magnet-to-one HALL IC relation.

In the detecting device, when the movable member moves in association with the switch of the selection range, the selection range is determined based upon a magnetic force detected by each of the HALL ICs.

The HALL ICs as many as the magnets are required in the detecting device. Therefore, a manufacturing cost of the detecting device gets high.

Therefore, it is required to provide a detecting device of a less expensive structure.

### SUMMARY

Accordingly, the present invention is made in view of the above-described problem in the conventional technology, and an object of the present invention is to provide a detecting device of a less expensive structure.

A detecting device detecting an operation of a detection object according to the present invention, comprises:

a movable member that moves in association with the operation of the detection object;

a fixing member that movably supports the movable member;

a single magnet that is disposed in the movable member and in which an N pole and an S pole line in a movement direction of the movable member; and

a single magnetic sensor disposed in the fixing member, wherein

the magnetic sensor is arranged to be opposed to the magnet on a movement track of the magnet as viewed in a direction perpendicular to the movement direction of the movable member.

According to the present invention, it is possible to provide the detecting device less expensively.

### BRIEF DESCRIPTION OF THE DRAWINGS

Other objects, features, and advantages of the present invention will become more apparent from the following detailed description made with reference to the accompanying drawings, in which like parts are designated by like reference numbers and in which:

FIG. 1 is an exploded perspective view illustrating a detecting device according to an embodiment of the present invention;

FIG. 2A is a perspective view illustrating the detecting device as viewed from an oblique lower side according to the embodiment;

FIG. 2B is a perspective view illustrating the detecting device as viewed from an oblique upper side according to the embodiment;

FIG. 3A is a cross section illustrating the detecting device, taken on plane A in FIG. 2B according to the embodiment;

FIG. 3B is a cross section illustrating the detecting device, taken on plane B in FIG. 2B according to the embodiment;

FIG. 4 is a plan view illustrating a pole board as viewed from the upper side in a detent plate side according to the embodiment;

FIG. 5A is a perspective view illustrating a hub as viewed from an oblique upper side according to the embodiment;

FIG. 5B is a cross section illustrating the hub as viewed from the upper side, taken on plane A in FIG. 5A according to the embodiment;

FIG. 6 is a plan view illustrating the detent plate as viewed from the upper side according to the embodiment;

FIG. 7A is a plan view illustrating a movable member as viewed from the upper side in the detent plate side according to the embodiment;

FIG. 7B is a plan view illustrating the movable member as viewed from the lower side in the pole board side according to the embodiment;

FIG. 7C is a cross section illustrating the movable member, taken along line A-A in FIG. 7B according to the embodiment;

FIG. 7D is a plan view illustrating a magnet as viewed from the lower side in the pole board side according to the embodiment;

FIG. 8A is a diagram illustrating a positional relation between the magnet and a magnetic sensor in the detecting device according to the embodiment:

FIG. 8B is a diagram illustrating a positional relation between the magnet and the magnetic sensor in the detecting device according to the embodiment; and

FIG. 9 is a graph illustrating a relation between an output signal of a magnetic sensitive element in the magnetic sensor and a selection range in an automatic transmission according to the embodiment.

### DETAILED DESCRIPTION

Hereinafter, a detecting device according to an embodiment in the present invention will be explained with reference to the accompanying drawings.

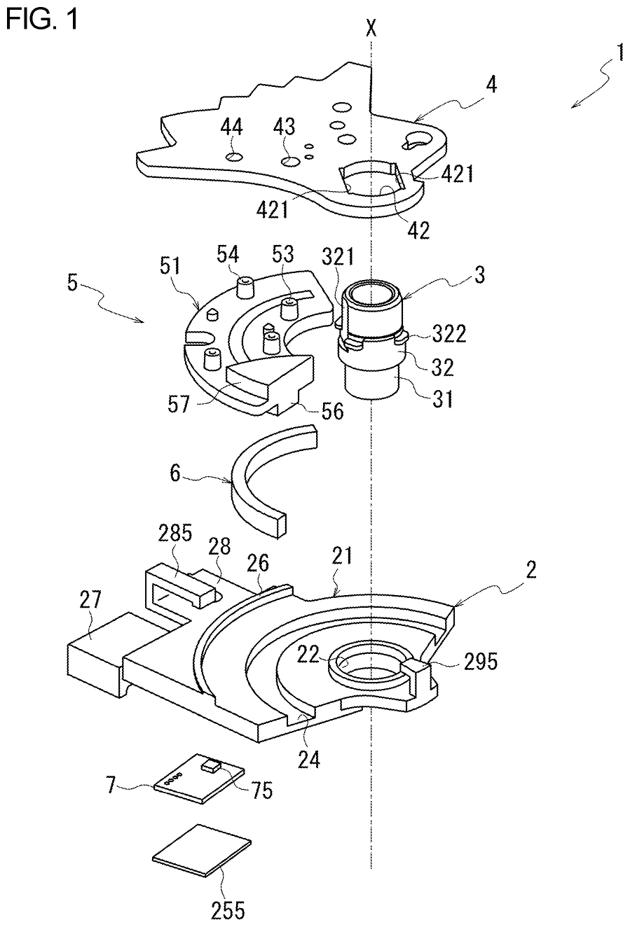

FIG. 1 is an exploded perspective view illustrating a detecting device 1. In FIG. 1, a magnet 6 is arranged outside of a movable member 5 for explaining a shape of the magnet 6 embedded in the inside of the movable member 5

In the following explanation, a positional relation of respective components in the detecting device 1 will be explained on a basis of an upper-lower direction in FIG. 1 for descriptive purposes.

The detecting device 1 is disposed in a transmission case of an automatic transmission, for example, and outputs a signal for determining a selection range in the automatic transmission.

The detecting device 1 is formed by assembling a pole board 2 fixed on the transmission case of the automatic transmission, a hub 3 supported by a support hole 22 of the pole board 2 to be rotatable therein, a detent plate 4 rotating together with the hub 3 and a movable member 5 rotating together with the detent plate 4 in a rotation axis X direction.

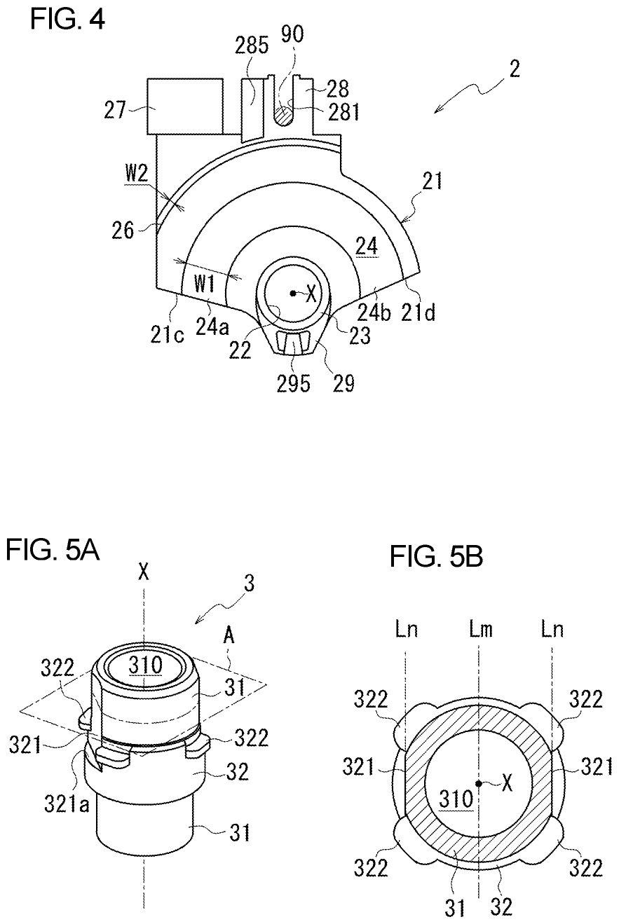

FIG. 4 is a plan view illustrating the pole board 2 from the upper side in the detent plate 4-side. However, the detent plate 4 is omitted in illustration of FIG. 4.

As illustrated in FIG. 4, the pole board 2 has a plate-shaped base portion 21 formed in an approximate fan shape as viewed in the rotation axis X direction. The base portion 21 is provided with the support hole 22 formed in a section corresponding to a fan top of the fan shape to support the hub 3.

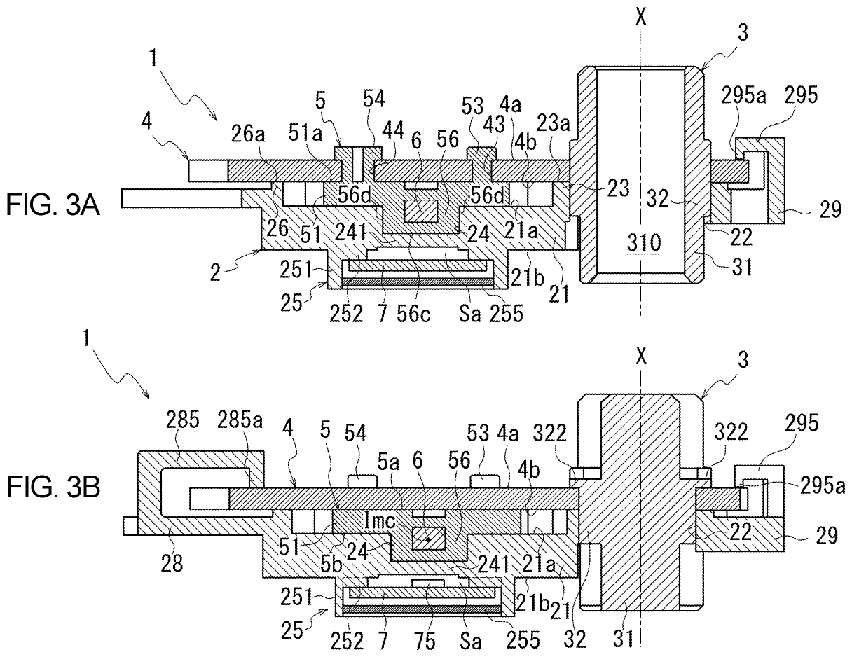

As illustrated in FIG. 3A, the support hole 22 is disposed to penetrate through the base portion 21 in a thickness direction (the rotation axis X direction).

A tubular wall 23 surrounding the support hole 22 is disposed on a top surface 21a of the base portion 21 in the detent plate 4-side. The tubular wall 23 projects to the upward side in the detent plate 4-side from the base portion 21. A top end 23a of the tubular wall 23 is formed as a flat surface perpendicular to the rotation axis X and supports a bottom surface 4b of the detent plate 4.

As illustrated in FIG. 4, a groove 24 is formed on an outer diameter side of the tubular wall 23 to surround the outer periphery of the tubular wall 23 at a predetermined interval. The groove 24 is formed in an arc shape having a predetermined width W1 in a radial direction of the rotation axis X as viewed in the rotation axis X direction.

As illustrated in FIG. 3A, the groove 24 opens on the top surface 21a of the base portion 21 in the detent plate 4-side.

As illustrated in FIG. 4, one end 24a and the other end 24b of the groove 24 in the longitudinal direction open to one side surface 21c and the other side surface 21d of the base portion 21 in the circumferential direction around the rotation axis X.

As shown in FIG. 3A, an accommodation portion 25 of a printed board 7 is disposed on a bottom surface 21b of the base portion 21 in a position at the opposite side of the groove 24 in the rotation axis X direction.

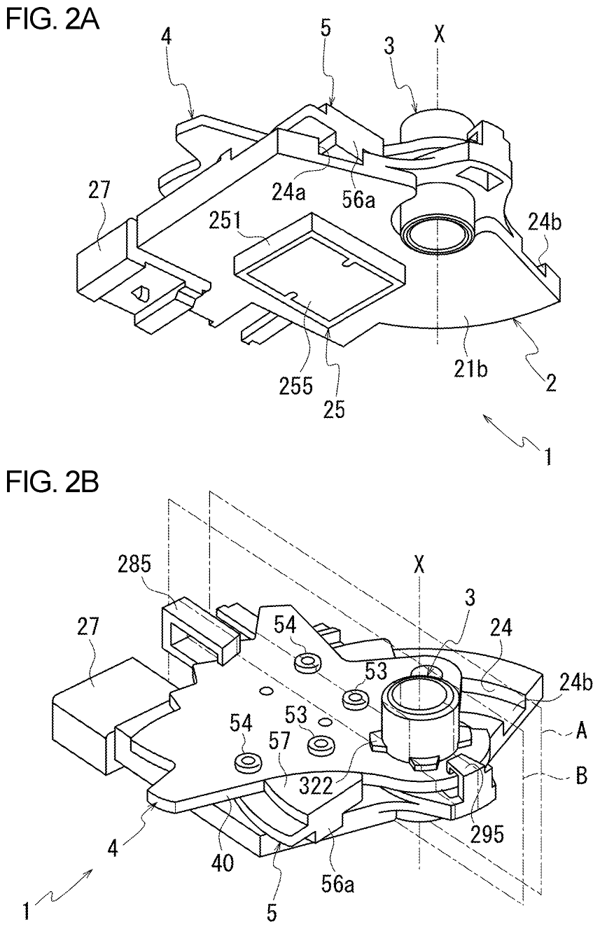

As illustrated in FIG. 2A, the accommodation portion 25 has a tubular wall 251 surrounding the outer periphery of the printed board 7. The accommodation portion 25 opens to the bottom surface 21b-side of the base portion 21 and an opening of the accommodation portion 25 is sealed by a sealing member 255.

As illustrated in FIG. 3A, a support portion 252 for supporting the printed board 7 is disposed in the inside of the tubular wall 251. The support portion 252 is disposed along the inner periphery of the tubular wall 251, and a space Sa is formed inside of the support portion 252 to avoid interference with a magnetic sensor 75 (refer to FIG. 3B) mounted on the printed board 7.

An area between the space Sa and the above-mentioned groove 24 is formed as a thin portion 241 a thickness of which is thin in the rotation axis X direction.

As illustrated in FIG. 4, a rib 26 is disposed in the outer diameter side of the groove 24 to surround the outer periphery of the tubular wall 23 at a predetermined interval. The rib 26 is formed in an arc shape having a predetermined width W2 in a radial direction of the rotation axis X as viewed in the rotation axis X direction.

As illustrated in FIG. 3A, the rib 26 projects upward in the detent plate 4-side from the base portion 21. A top end 26a of the rib 26 is formed as a flat surface perpendicular to the rotation axis X and supports a bottom surface 4b of the detent plate 4.

As illustrated in FIG. 4, in the base portion 21, a connector portion 27 and a connection portion 28 to a fixation-side member are disposed on the outer diameter side of the rib 26. The connector portion 27 and the connection portion 28 are arranged to be spaced from each other in the circumferential direction around the rotation axis X.

One end of a connection terminal extending from the printed board 7 is exposed to the inside of the connector portion 27.

The connection portion 28 is provided with an engaging groove 281 on an approximately central part thereof in the circumferential direction (a left-right direction in the figure) around the rotation axis X to open to the outer periphery side. A fixing member 90 in the transmission case side is inserted in the engaging groove 281 at the time of fixing the detecting device 1 in the inside of the transmission case, thus fixing a positional relation between the detecting device 1 and the transmission case.

The connection portion 28 is provided with a first support portion 285 in a position adjacent to the engaging groove 281.

As illustrated in FIG. 3B, the first support portion 285 is a band-shaped member that extends from the lower side to the upper side on the outer peripheral side of the detent plate 4 and further, extends to the rotation axis X-side. An abutting portion 285a abutting on the top surface 4a of the detent plate 4 projects downward to the detent plate 4-side at the tip end of the first support portion 285.

In the detecting device 1, the first support portion 285 is disposed to support the top surface 4a of the detent plate 4.

As illustrated in FIG. 4, the base portion 21 of the pole board 2 is provided with a swollen portion 29 near the tubular wall 23. The swollen portion 29 is swollen in a direction away from the rotation axis X and in a direction away from the connection portion 28.

The swollen portion 29 is provided with a second support portion 295 disposed in a position at the opposite side to the first support portion 285 across the rotation axis X.

As illustrated in FIG. 3A, the second support portion 295 is a band-shaped member that extends from the lower side to the upper side on the outer peripheral side of the detent plate 4 and further, extends to the rotation axis X-side.

An abutting portion 295a abutting on the top surface 4a of the detent plate 4 projects downward to the detent plate 4-side at the tip end of the second support portion 295.

In the detecting device 1, the second support portion 295 is disposed to support the top surface 4a of the detent plate 4.

FIG. 5A is a perspective view illustrating the hub 3 as viewed from an oblique upper side, and FIG. 5B is a cross section illustrating the hub 3, taken on plane A in FIG. 5A, as viewed from the upper side.

As illustrated in FIG. 3A, the hub 3 supported by the support hole 22 of the pole board 2 to be rotatable therein is disposed along the rotation axis X.

As illustrated in FIG. 5A, the hub 3 is provided with a tubular base portion 31 having a through hole 310 in which an unillustrated manual shaft is attached.

The base portion 31 is provided with a large diameter portion 32 at an approximately central part thereof in the rotation axis X direction. The large diameter portion 32 is formed with an outer dimeter substantially matched to an inner diameter of the support hole 22 (refer to FIG. 3A) on the pole board 2-side.

As illustrated in FIG. 5B, the large diameter portion 32 is provided with flat portions 321, 321 (width across flat portion).

The flat portions 321, 321 (width across flat portion) are formed by cutting the outer periphery of the large diameter portion 32 along straight lines Ln, Ln in parallel to a diameter line Lm of the hub 3 as viewed in the rotation axis X direction.

The flat portions 321, 321 are disposed in parallel to each other in a positional relation of being symmetrical across the rotation axis X as viewed in the rotation axis X direction.

As illustrated in FIG. 5A, the large diameter portion 32 is provided with the flat portions 321,321 toward the upper side from an approximately middle part in the rotation axis X direction. Therefore, in the hub 3 the flat portions 321,321 are disposed over the large diameter portion 32 and the base portion 31 positioned on the upper side of the large diameter portion 32.

The large diameter portion 32 is provided with stopper portions 322 in a region closer to the upper side than bottom sides 321a,321a of the flat portions 321,321. The stopper portions 322 comprise four portions that are disposed at equal intervals in the circumferential direction around the rotation axis X as viewed in the rotation axis X direction.

The stopper portions 322 abut on the top surface 4a of the detent plate 4 in the rotation axis X direction when the detent plate 4 is attached to the large diameter portion 32 (refer to FIG. 3B).

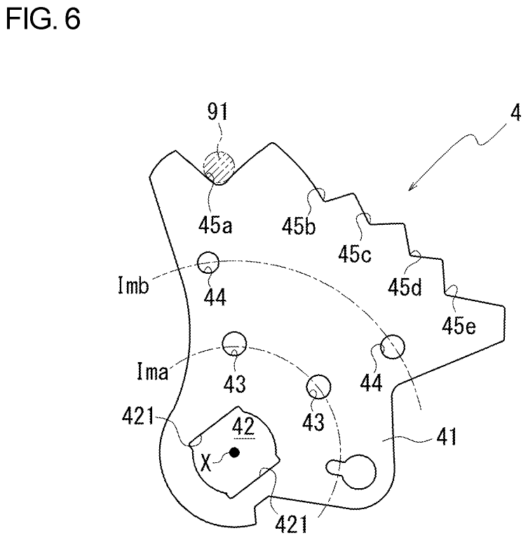

FIG. 6 is a plan view illustrating the detent plate 4 as viewed from the upper side in the detent plate 4-side.

The detent plate 4 has a plate-shaped base portion 41 formed in an approximate fan shape as viewed in the rotation axis X direction.

The base portion 41 is provided with a through hole 42 in a section corresponding to a fan top in the fan shape of the base portion 41.

The through hole 42 is provided with flat portions 421,421 (width across flat portion) in parallel to each other in a positional relation of being symmetrical across the rotation axis X. The detent plate 4 is attached to the hub 3 to be incapable of relatively rotating thereto with the engagement of the flat portions 421,421 to the above-mentioned flat portions 321,321 (width across flat portion) of the hub 3.

The base portion 41 is provided with a plurality of recessed portions 45 (45a to 45e) recessed to the rotation axis side in a section corresponding to a fan end in the fan shape of the base portion 41.

The detent plate 4 turns around the rotation axis X at the time of switching the selection range in the automatic transmission.

When the selection range in the automatic transmission is in a parking position, an engaging piece 91 of a detent spring (unillustrated) is elastically engaged to the recessed portion 45a. When the selection range in the automatic transmission is in a neutral position, the engaging piece 91 of the detent spring (unillustrated) is elastically engaged to the recessed portion 45c. When the selection range in the automatic transmission is in a low position, the engaging piece 91 of the detent spring (unillustrated) is elastically engaged to the recessed portion 45e.

The engaging piece 91 of the detent spring (unillustrated) is disposed to retain an angular position of the detent plate 4 around the rotation axis X to a predetermined position corresponding to the selection range in the automatic transmission.

The detent plate 4 is provided with attachment holes 43, 43 and attachment holes 44, 44 for attaching the after-mentioned movable member 5 on the outer diameter side of the through hole 42.

The attachment holes 43, 43 and the attachment holes 44, 44 penetrate through the base portion 41 of the detent plate 4 in a thickness direction (the rotation axis X direction).

As viewed in the rotation axis X direction, the attachment holes 43, 43 are disposed to be spaced from each other on a virtual circle Ima surrounding the rotation axis X at a predetermined interval.

As viewed in the rotation axis X direction, the attachment holes 44, 44 are disposed to be spaced from each other on a virtual circle Imb surrounding the rotation axis X at a predetermined interval.

The virtual circle Ima is a virtual circle with a diameter smaller than that of the virtual circle Imb. The attachment holes 43, 43 in the rotation axis X-side are positioned in the circumferential direction around the rotation axis X between the attachment holes 44, 44 adjacent to each other in the circumferential direction.

In the present embodiment, projections 53, 53 in the movable member 5-side are inserted in the attachment holes 43, 43 for swage. Projections 54, 54 in the movable member 5-side are inserted in the attachment holes 44, 44 for swage.

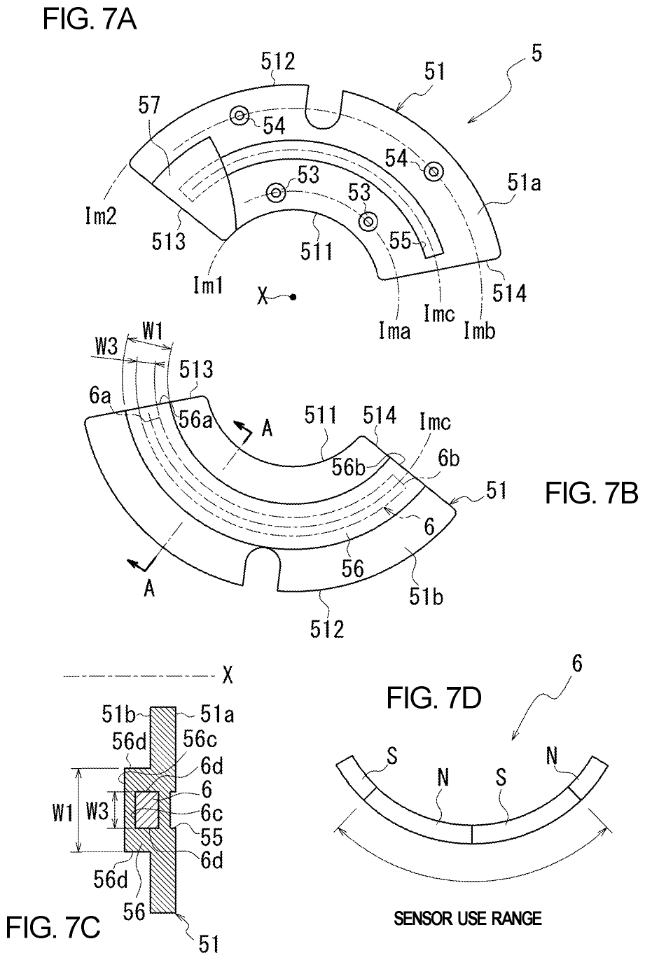

FIGS. 7A, 7B, 7C and 7D are diagrams explaining the movable member 5. FIG. 7A is a plan view illustrating the movable member 5 as viewed from the upper side in the detent plate 4-side. FIG. 7B is a plan view illustrating the movable member 5 as viewed from the lower side in the pole board 2-side. FIG. 7C is a cross section illustrating the movable member 5, taken along line A-A in FIG. 7B. FIG. 7D is a plan view illustrating the magnet 6 as viewed from the lower side in the pole board 2-side, explaining the magnet 6 embedded in the movable member 5.

As illustrated in FIG. 7A, the movable member 5 has a plate-shaped base portion 51 formed in an arc shape as viewed in the rotation axis X direction. The base portion 51 has an inner edge portion 511 along a virtual circle Im1 centered on the rotation axis X, and an outer edge portion 512 along a virtual circle Im2. The virtual circle Im1 is formed in a diameter smaller than that of the virtual circle Ima (refer to FIG. 6). The virtual circle Im2 is formed in a diameter larger than that of the virtual circle Imb (refer to FIG. 6).

Both sides of the inner edge portion 511 and the outer edge portion 512 in the circumferential direction around the rotation axis are respectively connected by a side edge portion 513 and a side edge portion 514 linearly extending in a radial direction of the rotation axis X.

Projections 53, 53 to be inserted in the attachment holes 43, 43 and projections 54, 54 to be inserted in the attachment holes 44, 44 are disposed on a top surface 51a of the base portion 51 in the detent plate 4-side.

The projections 53, 53, 54, 54 project to the upper side in the detent plate 4-side from the top surface 51a of the base portion 51.

As viewed in the rotation axis X direction, the projections 53, 53 are disposed to be spaced from each other on the virtual circle Ima surrounding the rotation axis X at a predetermined interval.

As viewed in the rotation axis X direction, the projections 54,54 are disposed to be spaced from each other on the virtual circle Imb surrounding the rotation axis X at a predetermined interval.

As described above, the projections 53, 53, 54, 54 in the movable member 5-side are inserted in the attachment holes 43, 43, 44, 44 in the detent plate 4-side for swage (refer to FIG. 3A).

When the detent plate 4 turns around the rotation axis X in this state, the movable member 5 turns around the rotation axis X together with the detent plate 4.

A recessed portion 55 formed in an arc shape as viewed in the rotation axis X direction is disposed in a region between the virtual circle Ima and the virtual circle Imb in the base portion 51. The recessed portion 55 extends along the virtual circle Imc. The after-mentioned arc-shaped magnet 6 (refer to FIG. 7B, virtual line) is embedded in the recessed portion 55.

The base portion 51 is provided with an abutting portion 57 disposed in the side edge portion 513 on one side in the circumferential direction around rotation axis X. The abutting portion 57 is disposed to project upward in the detent plate 4-side from the base portion 51.

As illustrated in FIG. 2B, the abutting portion 57 is disposed to make contact with a side edge 40 of the detent plate 4 at the time of fixing the movable member 5 to the detent plate 4, thus suppressing the looseness of the movable member 5.

As illustrated in FIG. 7B, an engaging portion 56 to be engaged to the groove 24 (refer to FIG. 4) in the pole board 2-side is disposed on a bottom surface 51b of the base portion 51 opposing the detent plate 4.

As illustrated in FIG. 7C, in the base portion 51 the engaging portion 56 projects to the pole board 2-side (the left side in the figure) from a position at the opposite side to the recessed portion 55 in the rotation axis X direction.

As illustrated in FIG. 7B, the engaging portion 56, as viewed in the rotation axis X direction, is formed in an arc shape. The engaging portion 56 is formed from the one side edge portion 513 to the other side edge portion 514 in the base portion 51 along the virtual circle Imc surrounding the rotation axis X at a predetermined interval.

The engaging portion 56 is formed with an equal width W1 over an entire length in the longitudinal direction. The width W1 is set to a width wider than a width W3 of the after-mentioned magnet 6.

As viewed in the rotation axis X, the engaging portion 56 is formed in a shape matched to the groove 24 in the pole board 2-side. As illustrated in FIG. 3A, when the detent plate 4 on which the movable member 5 is fixed is assembled via the hub 3 to the pole board 2 in the detecting device 1, the engaging portion 56 of the movable portion 5 is accommodated in the groove 24 in the pole board 2-side.

In the detecting device 1, the movable portion 5 turns around the rotation axis X in association with the turning of the detent plate 4 around the rotation axis X.

Here, the width W1 (refer to FIG. 7B) of the engaging portion 56 is set to the approximately same width as the width W1 (refer to FIG. 4) of the groove 24 in the pole board 2.

Further, a shape of the engaging portion 56 as viewed in the rotation axis X direction is formed in an arc shape matched to a shape of the groove 24 as viewed in the rotation axis X direction (refer to FIG. 4 and FIG. 7B).

Therefore, when the movable portion 5 turns around the rotation axis X in association with the turning of the detent plate 4 around the rotation axis X, the engaging portion 56 of the movable member 5 can slidably move in the groove 24 of the pole board 2 in the longitudinal direction of the groove 24.

In the movable member 5, the magnet 6 is embedded in the inside of the engaging portion 56. The magnet 6 is configured to be embedded in the inside of the movable member 5 at the time of resin-molding the movable member 5.

In this state, the magnet 6 is arranged to project from the base portion 51 of the movable member 5 to the pole board 2-side (refer to FIG. 3A).

As illustrated in FIG. 7B, in the movable member 5 one end 6a of the magnet 6 in the longitudinal direction is positioned near the one side edge portion 513 of the base portion 51, and the other end 6b is positioned near the other side edge portion 514.

Therefore, the one end 6a and the other end 6b of the magnet 6 are not exposed to the surface (the side edge portions 513, 514) of the movable member 5.

As illustrated in FIG. 7C, a side surface 6c of the magnet 6 in the pole board 2-side and both of side surfaces 6d, 6d in the width direction are positioned in the inside of the movable member 5, and are not exposed to the surface of the movable member 5. Therefore, the magnet 6 is completely embedded in the inside of the movable member 5, and magnetic elements pulled in by a magnetic force of the magnet 6 do not directly adhere to the surface of the magnet 6.

As illustrated in FIG. 7D, the magnet 6 is, as viewed in the rotation axis X direction, formed in an arc shape. As illustrated in FIG. 7B, the magnet 6 is embedded within a range shown in a virtual line along the virtual circle Imc surrounding the rotation axis X at a predetermined interval in the figure.

As illustrated in FIG. 7D, in the magnet 6 S poles and N poles alternately line in the longitudinal direction of the magnet 6. In the present embodiment, one set of the S pole and the N pole positioned in the central part in the longitudinal direction are set in a range (in a sensor use range) used for detection of an angular position of the movable member 5 (the detent plate 4) around the rotation axis X.

The S pole and the N pole positioned in both ends of the longitudinal direction are a magnet not used for detection of the angular position of the movable member 5 and are disposed to prevent the magnetic elements pulled in by the magnetic force of the magnet 6 from affecting the detection of the angular position of the movable member 5.

As described above, the movable member 5 (detent plate 4) turns around the rotation axis X at the time of switching the selection range in the automatic transmission. Therefore, the magnet 6 embedded in the movable member 5 moves in the circumferential direction around the rotation axis X at the time of switching the selection range in the automatic transmission.

As described above, the magnet 6 is disposed along the virtual circle Imc as viewed in the rotation axis X direction. Therefore, when the movable member 5 moves in the circumferential direction around the rotation axis X, the magnet 6 moves along the virtual circle Imc as viewed in the rotation axis X direction. That is, the virtual circle Imc shows a movement track of the magnet 6.

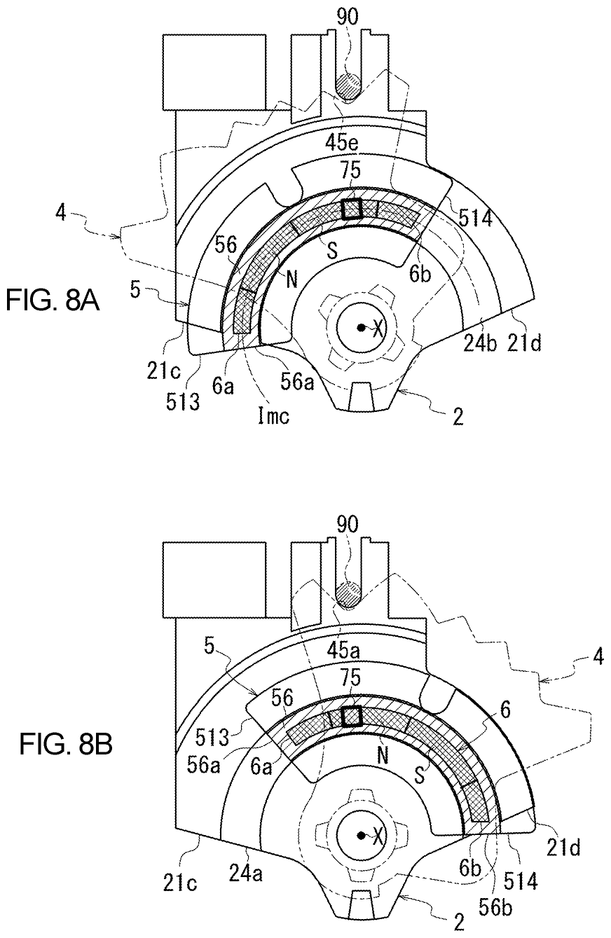

FIGS. 8A and 8B are diagrams explaining an operation of the detecting device 1. FIG. 8A is a diagram explaining a positional relation between the magnet 6 and the magnetic sensor 75 when the selection range in the automatic transmission is in a low position. FIG. 8B is a diagram explaining the positional relation between the magnet 6 and the magnetic sensor 75 when the selection range in the automatic transmission is in a parking position.

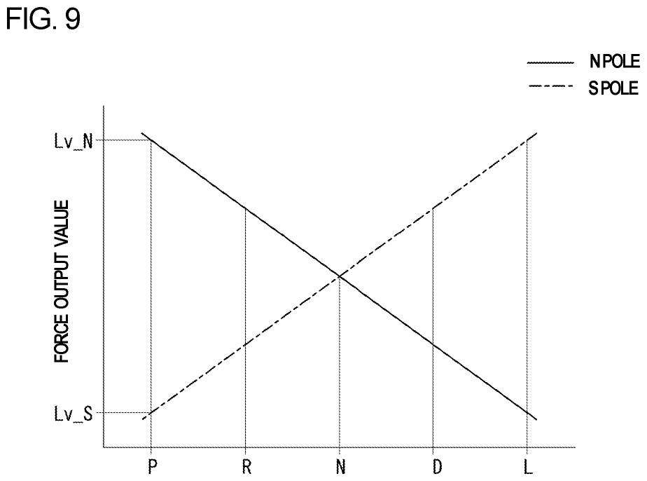

FIG. 9 is a graph illustrating a relation between an output signal of a magnetic sensitive element in the magnetic sensor 75 and the selection range in the automatic transmission.

The magnetic sensor 75 disposed in the pole board 2 is installed to meet the following condition in the detecting device 1.

In a cross-sectional view along the rotation axis X, the magnetic sensor 75 is arranged to be opposed to the magnet 6 and to be spaced therefrom in the rotation axis X direction under the virtual circle Imc showing the movement track of the magnet 6 in the movable member 5-side (refer to FIG. 3B).

As viewed in the rotation axis X direction, the magnetic sensor 75 is arranged in a position intersecting with the virtual circle Imc showing the movement track of the magnet 6 in the movable member 5-side (refer to FIG. 8A).

(C) In any case when the selection range in the automatic transmission is in the low position (refer to FIG. 8A) and when the selection range in the automatic transmission is in the parking position (refer to FIG. 8B), the magnetic sensor 75 is arranged to be opposed to one of the S pole and the N pole positioned in the central part of the magnet 6 in the longitudinal direction.

The present embodiment adopts a single magnetic sensor that can detect both of a magnetic force of the N pole and a magnetic force of the S pole as the magnetic sensor 75.

Specifically, the magnetic sensor 75 is provided with a single magnetic sensitive element detecting a change in a magnetic force of the N pole and a single magnetic sensitive element detecting a change in a magnetic force of the S pole.

The detecting device 1 outputs an output signal of the magnetic sensitive element detecting a change in a magnetic force of the N pole and an output signal of the magnetic sensitive element detecting a change in a magnetic force of the S pole via a wire connected to the connector portion 27 to an exterior.

For example, in a case where the selection range in the automatic transmission is in a parking “P” position, as illustrated in FIG. 8B the magnetic sensor 75 is arranged in a position to be opposed to the N pole of the magnet 6.

In this state, as illustrated in FIG. 9 an output value Lv_N of the magnetic sensitive element detecting the magnetic force of the N pole is larger than an output value Lv_S of the magnetic sensitive element detecting the magnetic force of the S pole.

An external device that receives an output signal of the detecting device 1 is set to determine that the selection range in the automatic transmission is in the parking “P” position when the output value of the magnetic sensitive element detecting the magnetic force of the N pole becomes the maximum value and when the output value of the magnetic sensitive element detecting the magnetic force of the S pole becomes the minimum value.

Hereinafter, determination criteria of the selection range in the automatic transmission will be listed.

When the output value of the magnetic sensitive element detecting the magnetic force of the N pole and the output value of the magnetic sensitive element detecting the magnetic force of the S pole each are not any one of the maximum value and the minimum value and when the output value of the magnetic sensitive element detecting the magnetic force of the N pole is larger than the output value of the magnetic sensitive element detecting the magnetic force of the S pole, the selection range in the automatic transmission is determined to be in a reverse (backward travel range) “R” position.

When the output value of the magnetic sensitive element detecting the magnetic force of the N pole and the output value of the magnetic sensitive element detecting the magnetic force of the S pole each are an approximately intermediate value between the maximum value and the minimum value and when the output value of the magnetic sensitive element detecting the magnetic force of the N pole is approximately equal to the output value of the magnetic sensitive element detecting the magnetic force of the S pole, the selection range in the automatic transmission is determined to be in a neutral “N” position.

When the output value of the magnetic sensitive element detecting the magnetic force of the N pole and the output value of the magnetic sensitive element detecting the magnetic force of the S pole each are not any one of the maximum value and the minimum value and when the output value of the magnetic sensitive element detecting the magnetic force of the N pole is smaller than the output value of the magnetic sensitive element detecting the magnetic force of the S pole, the selection range in the automatic transmission is determined to be in a drive (forward travel range) “D” position.

The selection range in the automatic transmission is determined to be in a low “L” position when the output value of the magnetic sensitive element detecting the magnetic force of the N pole becomes the minimum value and when the output value of the magnetic sensitive element detecting the magnetic force of the S pole becomes the maximum value.

It should be noted that a determination of the selection range by comparison between the output value of the magnetic sensitive element of the N pole and a threshold value and a determination of the selection range by comparison between the output value of the magnetic sensitive element of the S pole and a threshold value may be combined.

In this case, in a case where the selection range determined by the output value of the magnetic sensitive element of the N pole corresponds to the selection range determined by the output value of the magnetic sensitive element of the S pole, the corresponding selection range is determined to be the selection range in the automatic transmission. It should be noted that in a case of non-correspondence, for example, the magnetic sensor 75 is determined to be abnormal, and the abnormality of the magnetic sensor 75 can be notified.

Here, in a case where the magnetic sensor 75 is provided with the single magnetic sensitive element only that detects the magnetic force of the N pole or the S pole, an output signal of any one of a solid line (a characteristic line showing an output change in the magnetic sensitive element of the N pole) and a dashed-dotted line (a characteristic line showing an output change in the magnetic sensitive element of the S pole) in FIG. 9 is outputted from the detecting device 1.

In this case, the selection range in the automatic transmission is determined by the comparison between the output value of the magnetic sensitive element and the threshold value.

The magnetic sensor 75 provided with the magnetic sensitive element detecting the magnetic force of the N pole and the magnetic sensitive element detecting the magnetic force of the S pole each has two determination criteria for determining the selection range. Therefore, the determination accuracy improves more than in a case where the magnetic sensor 75 is provided with the single magnetic sensitive element only detecting the magnetic force of the N pole or the S pole.

Further, even in a case where one of the magnetic sensitive element detecting the magnetic force of the N pole and the magnetic sensitive element detecting the magnetic force of the S pole is damaged, it is possible to secure the function as the magnetic sensor 75. That is, it is possible to ensure redundancy of the detecting device 1.

An explanation will be made of the operation of the detecting device 1.

When the selection range in the automatic transmission is changed from “the parking position” to “the low position”, the unillustrated manual shaft rotates to cause the hub 3 and the detent plate 4 to turn around the rotation axis X.

Thereby, the movable member 5 fixed to the detent plate 4 and the magnet 6 embedded in the inside of the movable member 5 move in the circumferential direction around the rotation axis X.

Then, the positional relation between the magnetic sensor 75 and the N pole and the S pole of the magnet 6 changes caused by the movement of the magnet 6 (refer to FIGS. 8A and 8B).

As described above, since the magnetic sensor 75 is provided with one magnetic sensitive element detecting the magnetic force of the N pole and one magnetic sensitive element detecting the magnetic force of the S pole, the magnetic sensor 75 outputs an output signal showing the detected magnetic force of the N pole and an output signal showing the detected magnetic force of the S pole.

Thereby, the external equipment device that has received the output signals determines the angular position of the detent plate 4 around the rotation axis X from each of the output signal showing the detected magnetic force of the N pole and the output signal showing the detected magnetic force of the S pole to determine the selection range in the automatic transmission.

Specifically, when the selection range is changed from “the parking position” to “the low position”, the positional relation between the magnetic sensor 75 and the magnet 6 changes from the positional relation illustrated in FIG. 8B to the positional relation illustrated in FIG. 8A.

Thereby, the output signal of the magnetic sensor 75 changes from a state (A) to a state (B) as followed.

The state (A): the output value of the magnetic sensitive element detecting the magnetic force of the N pole is the maximum value and the output value of the magnetic sensitive element detecting the magnetic force of the S pole is the minimum value.

The state (B): the output value of the magnetic sensitive element detecting the magnetic force of the N pole is the minimum value and the output value of the magnetic sensitive element detecting the magnetic force of the S pole is the maximum value.

In this way, the output value of the magnetic sensitive element detecting the magnetic force of the N pole and the output value of the magnetic sensitive element detecting the magnetic force of the S pole change in response to the switching of the selection range in the automatic transmission. As a result, the selection range in the automatic transmission can be determined in the external equipment device into which the output signal of the detecting device 1 (the magnetic sensor 75) is inputted.

Here, at the switching of the selection range in the automatic transmission, the engaging portion 56 of the movable member 5 moves within the groove 24 of the pole board 2 in the longitudinal direction (in the circumferential direction around the rotation axis X) of the groove 24.

As described above, the magnet 6 is covered with a resin material configuring the movable member 5, and is thereby configured in such a manner as to prevent magnetic elements from directly adhering to the magnet 6 even in a case where metallic powder (magnetic elements) in the automatic transmission is pulled in by the magnetic force.

Further, since the engaging portion 56 has both side surfaces 56d along the movement direction in the groove 24 and a bottom surface 56c in the pole board 2-side that are covered with the resin material configuring the pole board 2, the magnetic elements do not adhere to both the side surfaces 56d and the bottom surface 56c as well (refer to FIG. 3A).

On the other hand, since one end 56a and the other end 56b of the engaging portion 56 in the longitudinal direction are exposed to the inside of the groove 24, the magnetic elements possibly adhere.

In the present embodiment, one set of the S pole and the N pole positioned in the central part of the magnet 6 in the longitudinal direction is a magnet used for the detection of the selection range by the magnetic sensor 75, and the S pole and the N pole positioned in both ends of the magnet 6 in the longitudinal direction are a magnet not used for the detection of the selection range by the magnetic sensor 75.

Therefore, even if the magnetic elements pulled in by the magnetic force of the magnet 6 adhere to the one end 56a and the other end 56b of the engaging portion 56 in the longitudinal direction, an effect of the magnetic elements having adhered thereto is caused to stay in the magnet (the N pole and the S pole) in both the ends not used for the detection by the magnetic sensor 75.

Therefore, even if the magnetic elements pulled in by the magnetic force of the magnet 6 adhere to the one end 56a and the other end 56b of the engaging portion 56 in the longitudinal direction, the effect of the magnetic elements having adhered thereto is configured in such a manner as not to reach the magnetic force of the magnet (the N pole and the S pole) in the central part used for the detection by the magnetic sensor 75.

As a result, the angular position of the detent plate 4 around the ration axis X can be accurately determined to determine the selection range in the automatic transmission.

In addition, in the present embodiment a length of the engaging portion 56 in the circumferential direction around the ration axis X is set such that when the selection range in the automatic transmission becomes “in the parking position”, the one end 56a of the engaging portion 56 projects outside from the groove 24, and when the selection range in the automatic transmission becomes “in the low position”, the other end 56b of the engaging portion 56 projects outside from the groove 24 (refer to FIG. 2A, FIG. 8A and FIG. 8B).

Therefore, even if the magnetic elements pulled in by the magnetic force of the magnet stagnate in the inside of the groove 24, when the engaging portion 56 moves in the circumferential direction around the rotation axis X at the switching of the selection range, the magnetic elements stagnant in the inside of the groove 24 are pushed by the one end 56a or the other end 56b of the engaging portion 56 to be discharged outside of the groove 24.

As a result, the event that the magnetic elements stagnant in the inside of the groove 24 get together to interrupt the movement of the movable member 5 (the engaging portion 56) is prevented from being caused.

As described above, the detecting device 1 according to the present embodiment has the configuration as follows.

The detecting device 1 includes the movable member 5, the pole board 2 (the fixing member), the single magnet 6, and the single magnetic sensor 75.

The movable member 5 moves in the circumferential direction around the rotation axis X in association with the switching in the selection range in the automatic transmission.

The pole board 2 supports the hub 3 rotating together with the movable member 5 to be rotatable around the rotation axis X.

The magnet 6 is disposed in the movable member 5, and the N pole and the S pole line in the movement direction of the movable member 5 (in the circumferential direction around the rotation axis X).

The magnetic sensor 75 is disposed on the printed board 7 installed on the pole board 2.

As viewed in the direction (the rotation axis X direction) perpendicular to the movement direction of the movable member 5, the magnetic sensor 75 is arranged to be opposed to the magnet 6 on the movement track (the virtual circle Imc) of the magnet 6.

With this configuration, when the positional relation between the magnetic sensor 75 and the magnet 6 changes caused by the movement of the movable member 5, the magnetic force that is detected by the magnetic sensor 75 changes. Thereby, the selection range in the automatic transmission can be determined based upon a magnitude of the magnetic force detected by the magnetic sensor 75.

Since the selection range in the automatic transmission can be detected by a combination of the single magnet 6 and the single magnetic sensor 75, it is possible to provide the detecting device 1 less expensively.

The detecting device 1 according to the present embodiment has the configuration as follows.

The magnet is disposed to project to the pole board 2-side from the movable member 5.

The groove 24 capable of accommodating the magnet 6 is disposed in the opposing portion of the pole board 2 to the movable member 5.

As viewed in the rotation axis X direction, the groove 24 is disposed along the movement track (the virtual circle Imc) of the magnet 6, and the one end 24a and the other end 24b of the groove 24 in the longitudinal direction open to the side surface 21c and the side surface 21d of the pole board 2.

In the magnet 6, the magnet (the N pole and the S pole) not used for the detection by the magnetic sensor 75 are connected to the one end 6a and the other end 6b in the longitudinal direction along the movement direction.

The magnetic elements pulled in by the magnetic force of the magnet 6 possibly advance into the groove 24.

The groove 24 in which the magnet 6 moves in association with the movement of the movable member 5 is configured such that the one end 24a and the other end 24b of the groove 24 in the longitudinal direction open to the side surfaces 21c, 21d of the pole board 2.

In a case where the magnet (a dummy magnet) not used for the detection by the magnetic sensor 75 is not disposed, when the magnetic element having advanced into the groove 24 adheres to the magnet 6, the detection of the magnetic force by the magnetic sensor 75 is affected. As a result, there is a possibility that the selection range in the automatic transmission cannot be appropriately detected.

Since the dummy magnet is not used for the detection of the magnetic sensor 75, even if the magnetic element adheres to a portion of the dummy magnet, the detection by the magnetic sensor 75 is not affected. Thereby, it is possible to appropriately detect the selection range in the automatic transmission.

The detecting device 1 according to the present embodiment has the configuration as follows.

The magnet 6 is embedded in the resin material as a constituent material of the movable member 5.

The magnet 6 is embedded in the engaging portion 56 formed integrally with the movable member 5.

With this configuration, the surface of the magnet 6 is protected with the constituent material (resin material: non-magnetic element) of the movable member 5. The magnet 6 slides and moves in the longitudinal direction in the inside of the groove 24. Since the surface of the magnet 6 is protected by the engaging portion 56 of the movable member 5, it is possible to prevent the abrasion of the magnet 6.

In addition, the magnetic element having advanced into the groove 24 can be prevented from making direct contact with the surface of the magnet 6.

In addition, even in a case where the magnetic element in the groove 24 adheres to the surface of the engaging portion 56 of the movable member 5, since a retaining force of the magnetic element is weaker than in a case where the magnetic element directly adheres to the magnet 6, it is possible to remove the magnetic element having adhered to the surface of the movable member 5 at a time point when the magnet 6 reaches the opening of the one end 24a or the other end 24B of the groove 24.

The detecting device 1 according to the present embodiment has the configuration as follows.

The magnetic sensor 75 comprises a single magnetic sensor that can detect the magnetic force of the N pole and the magnetic force of the S pole simultaneously.

When the positional relation between the magnetic sensor 75 and the magnet 6 changes caused by the movement of the movable member 5, the magnetic force of the N pole and the magnetic force of the S pole that are detected by the magnetic sensor 75 change. When a magnetic sensor that can detect both of the magnetic force of the N pole and the magnetic force of the S pole to be detected is adopted, it is possible to determine the selection range in the automatic transmission by using both of the detected magnetic force of the N pole and the detected magnetic force of the S pole. Therefore, the detection accuracy improves.

The detecting device 1 according to the present embodiment has the configuration as follows.

The movable member 5 is supported through the detent plate 4 and the hub 3 to be rotatable around the rotation axis X by the pole board 2.

As viewed in the rotation axis X direction, the magnet 6 and the groove 24 are formed in an arc shape surrounding the rotation axis X at a predetermined interval.

With this configuration, it is possible to provide the detecting device 1 inexpensively that is difficult to be subjected to the influence of the metallic powder (the magnetic element) in the transmission case.

In addition, since the detecting device 1 configured such that the movable member 5 turns around the rotation axis X can be miniaturized, a degree of freedom in the installation in the transmission case improves.

In the embodiment, the detected device 1 configured such that the movable member 5 and the magnet 6 turn around the rotation axis X is shown as an example, but a detected device configured such that the movable member 5 and the magnet 6 move forward/backward in an axial direction may be adopted.

In this case, a magnet in which N poles and S poles alternately line is formed in a straight line shape, and a magnet not used for detection by the magnetic sensor 75 is connected to both ends of the magnet in the longitudinal direction and the magnet is embedded in a constituent material of a movable member. As a result, the same effect as that of the above-mentioned embodiment can be obtained.

It should be noted that in the embodiment, a case where the detecting device 1 detects the selection range in the automatic transmission is shown as an example. The present invention is not limited to the aspect of the embodiment.

For example, the present invention can be, in an equipment device in which one of a plurality of selections is selected by an operation of a detection object, used for determination of the selected selection.

For example, the present invention can be suitably applied to a switch device switching a selection in accordance with an angular position of a dial type knob around a rotation axis, a switch device switching a selection in accordance with a position of a knob linearly moving, and the like.

While only the selected embodiment and the modification examples have been chosen to illustrate the present invention, it will be apparent to those skilled in the art from this disclosure that various changes and modifications can be made therein without departing from the scope of the invention as defined in the appended claims. Furthermore, the foregoing description of the embodiment and the modification examples according to the present invention is provided for illustration only, and not for the purpose of limiting the invention as defined by the appended claims and their equivalents.

1. A detecting device detecting an operation of a detection object, comprising:
a movable member that moves in association with the operation of the detection object;
a fixing member that movably supports the movable member;
a single magnet that is disposed in the movable member and in which an N pole and an S pole line in a movement direction of the movable member; and
a single magnetic sensor disposed in the fixing member;
wherein the magnetic sensor is arranged to be opposed to the magnet on a movement track of the magnet as viewed in a direction perpendicular to the movement direction of the movable member.

2. The detecting device according to claim 1, wherein:
the magnet is disposed to project to the fixing member side from the movable member;
the fixing member has an opposing portion to the movable member, the opposing portion being provided with a groove capable of accommodating the magnet;
the groove has one end and the other end in a longitudinal direction that open to side surfaces of the fixing member; and
the magnet has one end and the other end in the longitudinal direction along the movement direction, to which a magnet not used for detection by the magnetic sensor is connected.

3. The detecting device according to claim 2, wherein the magnet is embedded in a constituent material of the movable member.

4. The detecting device according to claim 2, wherein:
the movable member is supported to be rotatable around a rotation axis by the fixing member; and
as viewed in a direction of the rotation axis, the magnet and the groove are formed in an arc shape surrounding the rotation axis at a predetermined interval.

5. The detecting device according to claim 1, wherein the magnetic sensor comprises a single magnetic sensor able to detect a magnetic force of the N pole and a magnetic force of the S pole simultaneously.

6. The detecting device according to claim 1, wherein the operation of the detection object includes a switching operation of a selection range in an automatic transmission.

7. The detecting device according to claim 3, wherein:
the movable member is supported to be rotatable around a rotation axis by the fixing member; and
as viewed in a direction of the rotation axis, the magnet and the groove are formed in an arc shape surrounding the rotation axis at a predetermined interval.

8. The detecting device according to claim 2, wherein the operation of the detection object includes a switching operation of a selection range in an automatic transmission.
